(19) United States
(12) Patent Application Publication
(10) Pub. No.: US 2025/0386119 A1
(43) Pub. Date: Dec. 18, 2025

(54) IMAGE SENSOR, AND ELECTRONIC DEVICE INCLUDING THE SAME

(71) Applicant: Samsung Electronics Co., Ltd., Suwon-si (KR)

(72) Inventors: HAEWON LEE, Suwon-si (KR); Junoh KIM, Suwon-si (KR)

(21) Appl. No.: 19/171,445

(22) Filed: Apr. 7, 2025

(30) Foreign Application Priority Data
Jun. 18, 2024 (KR) 10-2024-0079109

(51) Int. Cl. H04N 25/77; H04N 25/46; H04N 25/62; H10F 39/00; H10F 39/18

(52) U.S. Cl. CPC H04N 25/77; H04N 25/46; H10F 39/18; H10F 39/803; H10F 39/807; H10F 39/811; H04N 25/62

(57) ABSTRACT

An image sensor includes first and second pixel circuits connected to first and second floating diffusion (FD) nodes, respectively, first and second reset transistors resetting the first and second FD nodes in response to first and second reset signals, respectively, a first connection transistor connected between the first FD node and a common node and transferring photo charges of the first FD node to the common node, a second connection transistor connected between the second FD node and the common node and transferring photo charges of the second FD node to the common node, and a source follower transistor outputting a pixel signal corresponding to photo charges of the common node to a select transistor. The select transistor is connected between the source follower transistor and a column line and transfers the pixel signal to the column line in response to a selection signal.

### CROSS-REFERENCE TO RELATED APPLICATION(S)

This application claims priority under 35 U.S.C. § 119 to Korean Patent Application No. 10-2024-0079109 filed on Jun. 18, 2024, in the Korean Intellectual Property Office, the disclosure of which is incorporated by reference herein in its entirety.

### BACKGROUND

Embodiments of the present disclosure described herein relate to a semiconductor device, and more particularly, relate to an image sensor and an electronic device including the same.

An image sensor is a semiconductor device which converts an optical image into an electrical signal. With the development of the computer industry and the communication industry, nowadays, there is an increasing demand on a high-performance image sensor in various fields of electronic devices such as a digital camera, a camcorder, a personal communication system (PCS), a game console, a security camera, a medical micro camera. Image sensors may be classified into a charge coupled device (CCD) type image sensor and a complementary metal oxide semiconductor (CMOS) type image sensor. The CMOS type image sensor is abbreviated to CIS (CMOS image sensor). The CIS includes a plurality of pixels arranged in a two-dimensional structure. Each of the pixels includes a photodiode (PD). The photodiode plays a role of converting an incident light into an electrical signal.

In the CIS field, various techniques are being developed to improve reliability and a signal-to-noise ratio (SNR) of various signals and data which a pixel array of an image sensor generates.

### SUMMARY

Embodiments of the present disclosure provide an image sensor and an electronic device including the same.

According to an embodiment, an image sensor includes a first pixel circuit that is connected to a first floating diffusion (FD) node, a second pixel circuit that is connected to a second FD node, a first reset transistor that resets the first FD node in response to a first reset signal, a second reset transistor that resets the second FD node in response to a second reset signal, a first connection transistor that is connected between the first FD node and a common node and transfers photo charges of the first FD node to the common node in response to a first connection signal, a second connection transistor that is connected between the second FD node and the common node and transfer photo charges of the second FD node to the common node in response to a second connection signal, and a source follower transistor that outputs a pixel signal corresponding to photo charges of the common node to a select transistor, and the select transistor is connected between the source follower transistor and a column line and transfers the pixel signal to the column line in response to a selection signal.

According to an embodiment, an image sensor includes a pixel array, and a timing controller that controls the pixel array. The pixel array includes a first pixel circuit that is connected to a first floating diffusion (FD) node, a second pixel circuit that is connected to a second FD node, a first reset transistor that resets the first FD node in response to a first reset signal, a second reset transistor that resets the second FD node in response to a second reset signal, a first connection transistor that is connected between the first FD node and a common node and transfers photo charges of the first FD node to the common node in response to a first connection signal, a second connection transistor that is connected between the second FD node and the common node and transfers photo charges of the second FD node to the common node in response to a second connection signal, and a source follower transistor that outputs a pixel signal corresponding to photo charges of the common node to a select transistor, and the select transistor is connected between the source follower transistor and a column line and transfers the pixel signal to the column line in response to a selection signal.

According to an embodiment, an image sensor includes a substrate that includes a pixel region, a first pixel circuit and a second pixel circuit that are disposed in the pixel region of the substrate so as to be adjacent in a first direction, each of the first pixel circuit and the second pixel circuit including a plurality of sub-pixel circuits, a pixel isolation layer that penetrates the substrate and surrounds the pixel region, the pixel isolation layer isolating the plurality of sub-pixel circuits in the first direction and a second direction perpendicular to the first direction, a first floating diffusion (FD) node region that is disposed in the pixel region and is disposed adjacent to the plurality of sub-pixel circuits of the first pixel circuit, a second FD node region that is disposed in the pixel region and is disposed adjacent to the plurality of sub-pixel circuits of the second pixel circuit, a first transistor region that is disposed on the pixel region of the substrate and overlaps the first pixel circuit in a third direction perpendicular to the first direction and the third direction, and a second transistor region that is disposed on the pixel region of the substrate and overlaps the second pixel circuit in the third direction. Each of the plurality of sub-pixel circuits includes a photodiode configured to generate photo charges based on an incident light, and a transfer transistor stacked on the photodiode in the third direction, and configured to connect the photodiode to a corresponding FD node region of the first and second FD node regions. The first FD node region and the second FD node region are sequentially disposed in the first direction. The first transistor region includes a first high dual conversion gain transistor including a first end and a second end connected to the first FD node region, a first connection transistor including a first end and a second end connected to the first FD node region, a first source follower transistor including a first end and a gate terminal connected to the first end of the first connection transistor, a first select transistor including a first end and a second end connected to the first end of the first source follower transistor. The second transistor region includes a second high dual conversion gain transistor including a first end and a second end connected to the second FD node region, a second connection transistor including a first end and a second end connected to the second FD node region, a second source follower transistor including a first end and a gate terminal connected to the first end of the second connection transistor, and a second select transistor including a first end and a second end connected to the first end of the second source follower transistor. Each of the first and second source follower transistors transfers a pixel signal corresponding to photo charges of at least one of the first FD node region and the second FD node region, and includes the gate terminal electrically connected to: one of the first and second FD node regions through a corresponding one of the first and second connection transistors, or both of the first and second FD node regions through the first and second connection transistors. Each of the first and second select transistors outputs the transferred pixel signal from the first end of each of the first and second select transistors.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is a block diagram of an image sensor according to an embodiment of the present disclosure.

FIG. 3 is a circuit diagram illustrating a pixel array according to an embodiment of the present disclosure.

FIG. 4 is a circuit diagram describing a pixel circuit of a pixel array according to some embodiments of the present disclosure.

FIG. 5A is a circuit diagram describing a pixel array operating in a full mode, according to some embodiments of the present disclosure.

FIG. 5B is a circuit diagram describing a pixel array operating in a binning mode, according to some embodiments of the present disclosure.

FIG. 6 is a graph describing a signal-to-noise ratio (SNR) of a pixel signal according to some embodiments of the present disclosure.

FIG. 7 is a circuit diagram describing a pixel array according to some embodiments of the present disclosure.

FIG. 8 is a circuit diagram describing a pixel array according to some embodiments of the present disclosure.

FIG. 9 is a diagram describing a layout of a pixel array according to some embodiments of the present disclosure.

### DETAILED DESCRIPTION

Below, embodiments of the present disclosure will be described in detail and clearly to such an extent that one skilled in the art carries out embodiments of the present disclosure easily.

In the detailed description, components which are described with reference to the terms “unit”, “module”, “block”, “˜er or ˜or”, etc. and function blocks which are illustrated in drawings will be implemented in the form of software or hardware or a combination thereof. For example, the software may include a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

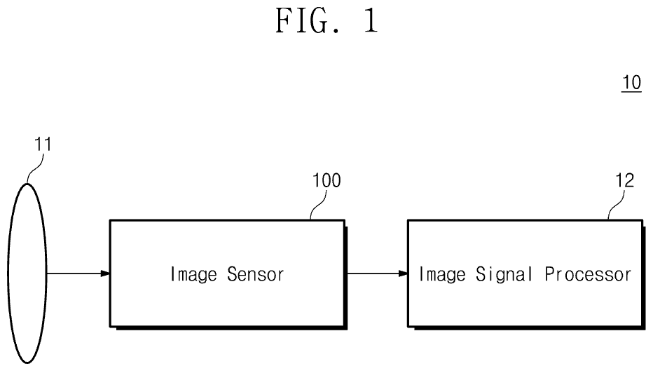

FIG. 1 is a block diagram of an electronic device according to an embodiment of the present disclosure. Referring to FIG. 1, an electronic device 10 may include an optical device 11, an image sensor 100, and an image signal processor (ISP) 12. The electronic device 10 may be implemented as a part of various electronic devices such as a smartphone, a digital camera, a laptop computer, and a desktop computer.

A light may be reflected by an object, a scenery, etc. targeted for photographing, and the optical device 11 (e.g., a camera lens and a structure including the camera lens) may receive the reflected light. The image sensor 100 may generate an electrical signal based on the light received through the optical device 11. For example, the image sensor 100 may be implemented with a complementary metal oxide semiconductor (CMOS) image sensor. For example, the image sensor 100 may be a multi-pixel image sensor having a dual pixel structure or a tetracell structure.

The image sensor 100 may include a pixel array. Pixels of the pixel array may convert a light into electrical signals and may generate pixel values. A ratio at which a light is converted into an electrical signal (e.g., a voltage) may be defined as “conversion gain”. In particular, the pixel array may generate pixel signals under a low conversion gain condition and a high conversion gain condition, by using a dual conversion gain in which a conversion gain changes.

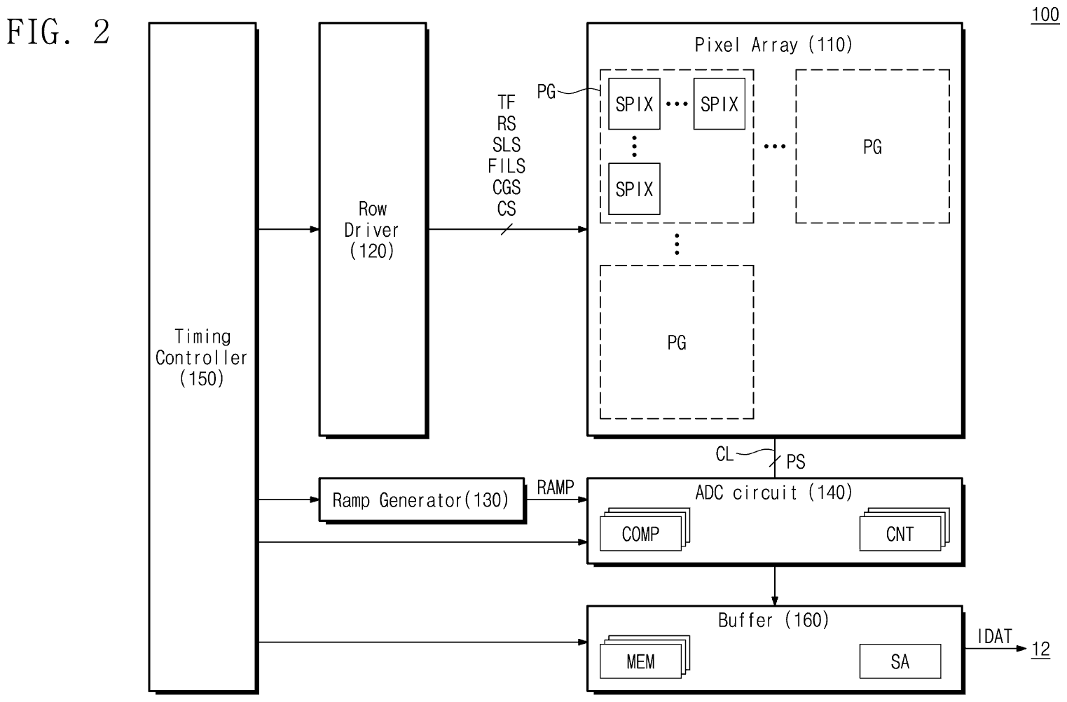

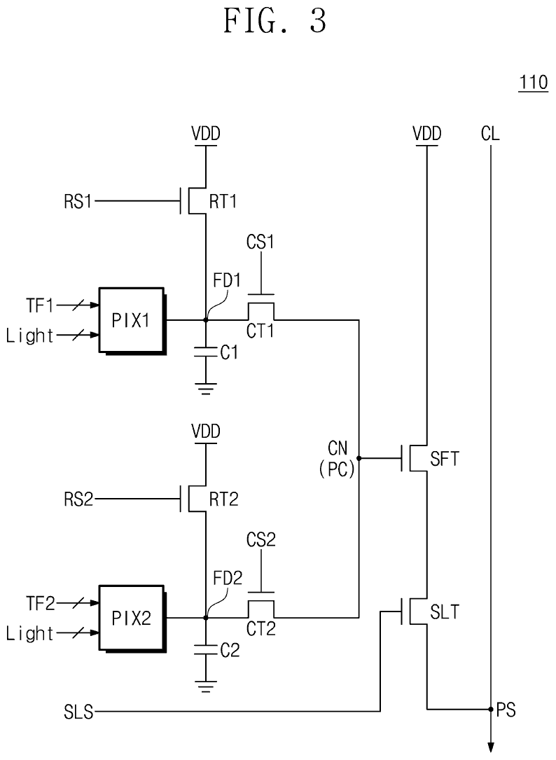

In addition, the image sensor 100 may include an analog-to-digital converting (ADC) circuit for performing correlated double sampling (CDS) for the pixel values. The image sensor 100 will be described in detail with reference to FIGS. 2 and 3 together.

The image signal processor 12 may generate image data associated with the photographed object or scenery, based on the electrical signals output from the image sensor 100. To this end, the image signal processor 12 may perform various processing such as color correction, auto white balance, gamma correction, color saturation correction, bad pixel correction, and hue correction.

For better understanding of the present disclosure, the description is given as the electronic device 10 includes one optical device 11 and one image sensor 100, but the present invention is not limited thereto. The electronic device 10 may include a plurality of optical devices and a plurality of image sensors. In this case, the plurality of optical devices may have different fields of view. Also, the plurality of image sensors may have different functions, different performances, and/or different characteristics and may include pixel arrays of different configurations.

FIG. 2 is a block diagram of an image sensor according to an embodiment of the present disclosure. Referring to FIG. 2, the image sensor 100 may include a pixel array 110, a row driver 120, a ramp signal generator 130, an analog-to-digital converter (ADC) circuit 140, a timing controller 150, and a buffer 160.

The pixel array 110 may include a plurality of pixel groups PG arranged along rows and columns in the form of a matrix. Each of the plurality of pixel groups PG may include a photoelectric conversion element. For example, the photoelectric conversion element may include a photodiode, a photo transistor, a photo gate, or a pinned photodiode. Herein, for convenience of description, the terms of the plurality of pixel groups PG and a pixel group PG may be used interchangeably.

The plurality of pixel groups PG constituting the pixel array 110 may include a plurality of sub-pixel circuits SPIX. The plurality of sub-pixel circuits SPIX may share one floating diffusion region (or floating diffusion (FD) node) or a plurality of floating diffusion regions. A plurality of sub-pixel circuits sharing one FD node may be referred to as “one pixel circuit”. For example, the pixel array 110 may include a plurality of pixel circuits PIX, and each of the plurality of pixel circuits PIX may include two or more sub-pixel circuits SPIX. Herein, for convenience of description, the terms of the plurality of pixel circuits PIX and a pixel circuit PIX may be used interchangeably.

The pixel group PG may include pixels of the same color. For example, the pixel group PG may include a red pixel to convert a light of a red spectrum into an electrical signal, a green pixel to convert a light of a green spectrum into an electrical signal, or a blue pixel to convert a light of a blue spectrum into an electrical signal. For example, the pixel groups PG constituting the pixel array 110 may be arranged in the form of a tetra-Bayer pattern. Also, a micro lens and a color filter may be stacked on/over each pixel. In association with the light incident through the micro lens, the color filter may transmit a light of a specific color, that is, a wavelength of a specific color zone, and a color which the pixel is capable of detecting may be determined depending on the color filter provided in the pixel.

Each of the plurality of pixel groups PG of the pixel array 110 may output a pixel signal PS to the ADC circuit 140 along a column line CL, based on the intensity or amount of light incident from the outside. For example, the pixel signal PS may be an analog signal corresponding to the intensity or amount of light incident from the outside.

The pixels of the pixel array 110 may be classified into active pixels and dummy pixels. The pixel groups PG illustrated in FIG. 2 may include the active pixels, and the dummy pixels may be located at the border of the pixel array 110, that is, to be adjacent to the boundary of the active pixels. The active pixels may receive the light reflected from an object and may convert the received light into electrical signals, and the dummy pixels may be shielded from an external light and may generate dark currents depending on a given factor (e.g., a temperature) regardless of a light.

The row driver 120 may select and drive a row of the pixel array 110. The row driver 120 may decode an address and/or a control signal generated by the timing controller 150 and may generate control signals for selecting and driving a row of the pixel array 110. For example, the control signals may include a signal for selecting a pixel, a signal for resetting a floating diffusion region, etc. In particular, the pixel array 110 according to an embodiment of the present disclosure may simultaneously read out pixels located at two rows, and the row driver 120 may select and drive two rows to be read out simultaneously.

The ramp signal generator 130 may generate a ramp signal RAMP under control of the timing controller 150. For example, the ramp signal generator 130 may operate in response to a control signal such as a ramp enable signal. When the ramp enable signal is activated, the ramp signal generator 130 may generate the ramp signal RAMP based on preset values (e.g., a start level, an end level, and a slope). For example, the ramp signal RAMP may be a signal which increases or decreases along a preset slope during a specific time period. The ramp signal RAMP may be provided to the ADC circuit 140.

The ADC circuit 140 may receive the pixel signals PS from the plurality of pixel circuits PIX of the pixel array 110 through column lines CL and may receive the ramp signal RAMP from the ramp signal generator 130. The ADC circuit 140 may operate based on a correlated double sampling (CDS) technique for obtaining a reset signal and an image signal from the received pixel signal PS and extracting a difference between the reset signal and the image signal as an effective signal component. The ADC circuit 140 may include a plurality of comparators COMP and a plurality of counters CNT.

Each of the comparators COMP may perform correlated double sampling (CDS) by comparing the reset signal of the pixel signal PS and the ramp signal RAMP and comparing the image signal of the pixel signal PS and the ramp signal RAMP. Each of the counter CNT may count pulses of the signal experiencing the correlated double sampling and may output a counting result as a digital signal.

The timing controller 150 may generate a control signal and/or a clock for controlling an operation and/or a timing of each of the row driver 120, the ramp signal generator 130, and the ADC circuit 140. For example, the timing controller 150 may generate a transfer signal TF, a reset signal RS, a selection signal SLS, a filler signal FILS, a dual conversion gain signal CGS, and a connection signal CS. Signals which the timing controller 150 generates will be described in detail with reference to FIGS. 3, 4, and 8 together.

The buffer 160 may include memories MEM and a sense amplifier SA. The memories MEM may store digital signals output from the corresponding counters CNT of the ADC circuit 140. The sense amplifier SA may sense and amplify the digital signals stored in the memories MEM. The sense amplifier SA may output the amplified digital signals as image data IDAT, and the image data IDAT may be provided to the image signal processor 12 of FIG. 1.

In some embodiments, the image sensor 100 may operate in a full mode. In the case of operating in the full mode, the image sensor 100 may perform correlated double sampling (CDS) for pixel values generated from all the active pixels of the image sensor 100 and may count pulses of the signal experiencing the correlated double sampling so as to be output as a digital signal.

In some embodiments, the image sensor 100 may operate in a binning mode. In the case of operating in the binning mode, the image sensor 100 may output a value (or an average value), which is obtained by summing pixel values generated from active pixels having the same type (e.g., the same color) from among all the active pixels of the pixel array 110, as a pixel signal PS.

FIG. 3 is a circuit diagram illustrating a pixel array according to an embodiment of the present disclosure. Referring to FIG. 3, the pixel array 110 may include a first pixel circuit PIX1, a second pixel circuit PIX2, a first FD node FD1, a second FD node FD2, a first reset transistor RT1, a second reset transistor RT2, a first connection transistor CT1, a second connection transistor CT2, a common node CN, a source follower transistor SFT, a select transistor SLT, and the column line CL.

For better understanding of the present invention, the description is given as the pixel array 110 includes one pixel group implemented with two pixel circuits, two FD nodes, two reset transistors, one source follower transistor, and one select transistor, but the present invention is not limited thereto. The pixel array 110 may include a plurality of pixel groups, and the different numbers of components may be used for the pixel groups.

Unlike a conventional pixel array including a pixel group implemented with one FD node and pixels sharing the FD node, the pixel array 110 of the present invention may include a pixel group implemented with two or more FD nodes and pixels (e.g., the first and second pixel circuits PIX1 and PIX2) sharing the two or more FD nodes.

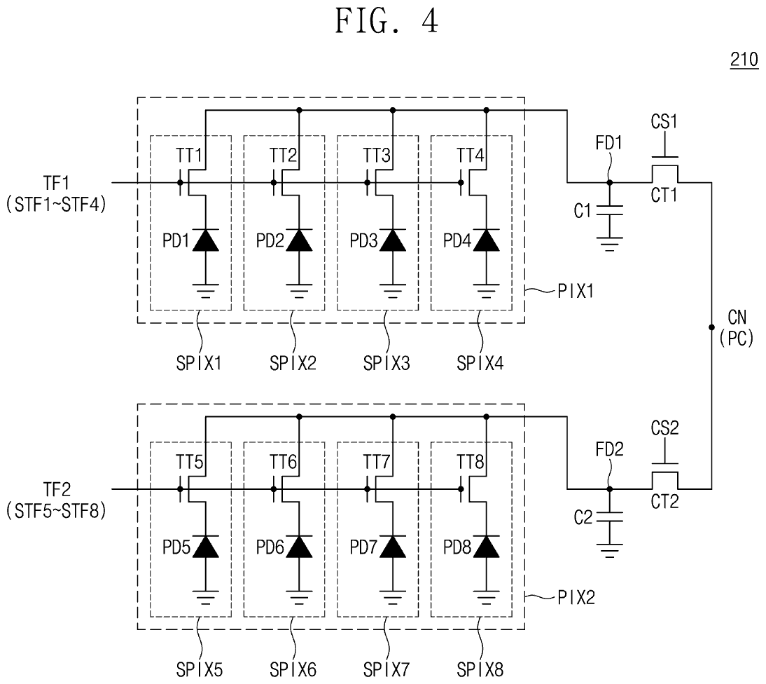

The first pixel circuit PIX1 may generate photo charges. For example, the first pixel circuit PIX1 may generate photo charges corresponding to an incident light in response to a first transfer signal TF1. The first pixel circuit PIX1 may receive the first transfer signal TF1 from the timing controller 150 of FIG. 2 through the row driver 120. The first pixel circuit PIX1 may include sub-pixel circuits sharing the first FD node FD1. The sub-pixel circuit will be described in detail with reference to FIG. 4.

The first pixel circuit PIX1 may operate in response to the first transfer signal TF1. For example, the first pixel circuit PIX1 may convert an incident light into photo charges (i.e., may generate photo charges) and may transfer the converted photo charges to the first FD node FD1 based on a logical value of the first transfer signal TF1. Also, the first pixel circuit PIX1 may not transfer the converted photo charges to the first FD node FD1 based on a logical value of the first transfer signal TF1.

The first FD node FD1 may store the photo charges. For example, the first FD node FD1 may store the photo charges received from the first pixel circuit PIX1. While the first pixel circuit PIX1 generates photo charges in response to the first transfer signal TF1, the first FD node FD1 may store the photo charges received from the first pixel circuit PIX1.

The capacity of the photo charges stored at the first FD node FD1 may correspond to a first capacitor C1. The first capacitor C1 may indicate a storage capacity of a parasitic capacitor of the first FD node FD1.

The first connection transistor CT1 may operate in response to a first connection signal CS1. The first connection transistor CT1 may receive the first connection signal CS1 from the timing controller 150 of FIG. 2 through the row driver 120. For example, the first connection transistor CT1 may be connected between the first FD node FD1 and the common node CN and may connect or disconnect the first FD node FD1 to or from the common node CN based on a logical value of the first connection signal CS1.

In some embodiments, when the first connection signal CS1 is at a logic high level, the first connection transistor CT1 may be turned on and may connect the first FD node FD1 to the common node CN. When the first FD node FD1 and the common node CN are connected by the first connection transistor CT1, the photo charges stored at the first FD node FD1 may be transferred to the common node CN.

Also, when the first connection signal CS1 is at a logic low level, the first connection transistor CT1 may be turned off and may disconnect the first FD node FD1 from the common node CN. When the first FD node FD1 and the common node CN are disconnected by the first connection transistor CT1, the photo charges stored at the first FD node FD1 may not be transferred to the common node CN.

The first reset transistor RT1 may reset the first FD node FD1. For example, the first reset transistor RT1 may periodically discharge photo charges stored at the first FD node FD1 in response to a first reset signal RS1. The first reset transistor RT1 may receive the first reset signal RS1 from the timing controller 150 of FIG. 2 through the row driver 120.

In detail, the first reset transistor RT1 may provide a power supply voltage VDD to the first FD node FD1 in response to the first reset signal RS1. In this case, the photo charges stored at the first FD node FD1 may move to a terminal for the power supply voltage VDD. For example, a voltage of the first FD node FD1 may be reset.

The second pixel circuit PIX2, the second FD node FD2, the second connection transistor CT2, and the second reset transistor RT2 are similar to the first pixel circuit PIX1, the first FD node FD1, the first connection transistor CT1, and the first reset transistor RT1, and thus, additional description will be omitted to avoid redundancy.

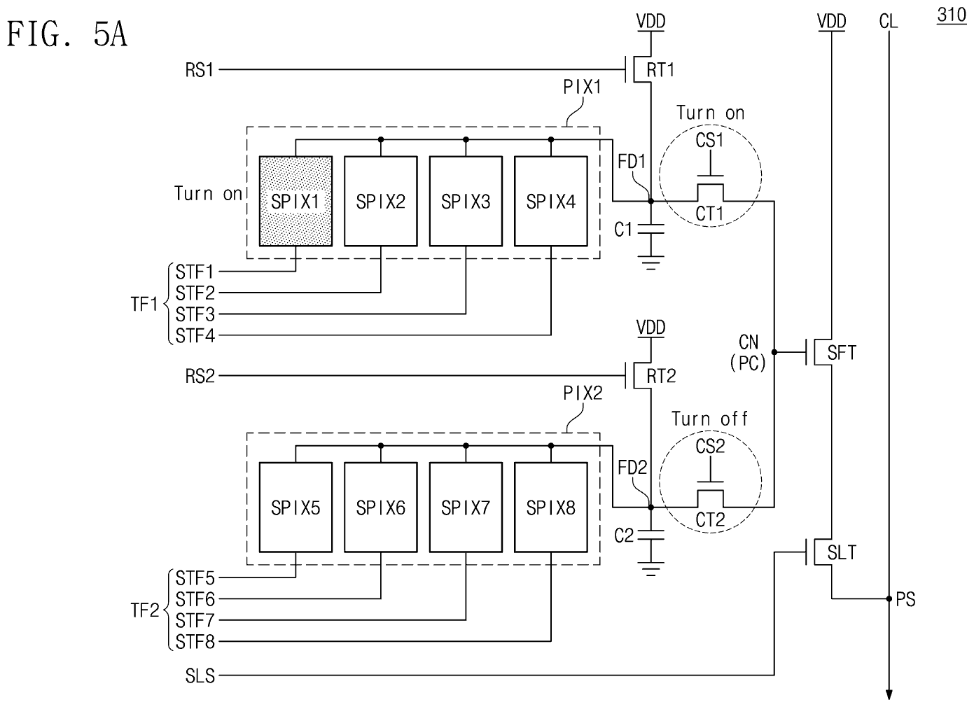

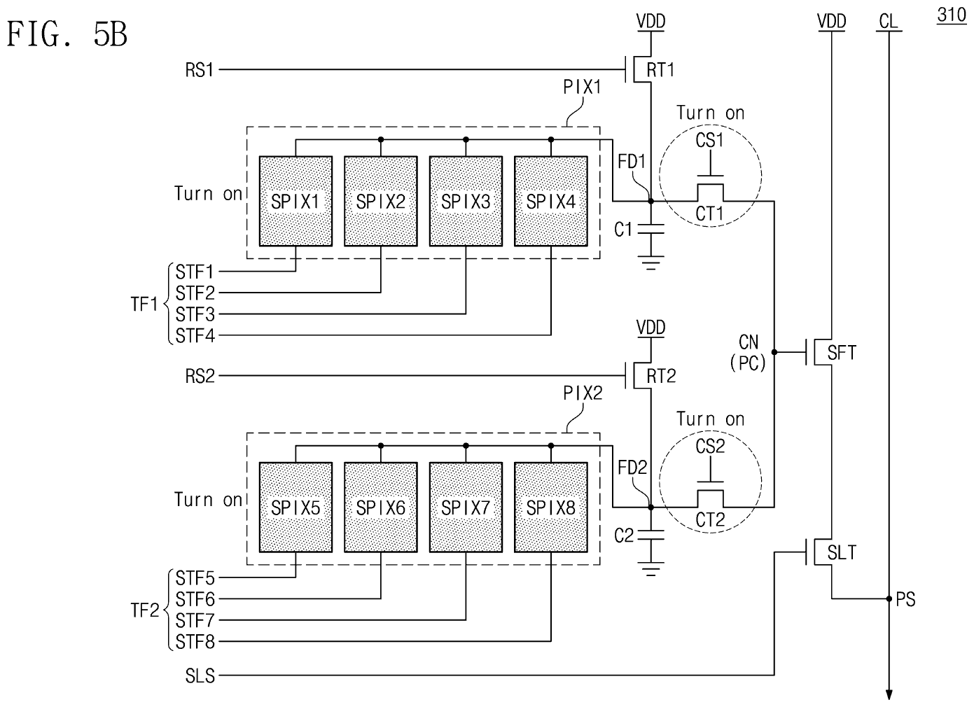

The source follower transistor SFT may generate the pixel signal PS. For example, the source follower transistor SFT may generate the pixel signal PS corresponding to photo charges PC of the common node CN. For example, a gate termina of the source follower transistor SFT may be connected to the common node CN. In some embodiments, the photo charges PC of the common node CN may correspond to the photo charges stored at the first FD node FD1 and/or the second FD node FD2. The photo charges PC of the common node CN will be described in detail with reference to FIGS. 5A and 5B.

The select transistor SLT may output the pixel signal PS to the column line CL. For example, the select transistor SLT may connect between the source follower transistor SFT and the column line CL and may output the pixel signal PS generated from the source follower transistor SFT to the column line CL in response to the selection signal SLS. The select transistor SLT may receive the selection signal SLS from the timing controller 150 of FIG. 2 through the row driver 120.

In some embodiments, the select transistor SLT may be turned on in response to the selection signal SLS having the logic high level and may transfer the pixel signal PS to the column line CL. The select transistor SLT may transfer the pixel signal PS to the ADC circuit 140 of FIG. 2 through the column line CL. Also, the select transistor SLT may be turned off in response to the selection signal SLS having the logic low level and may not transfer the pixel signal PS to the column line CL.

FIG. 4 is a diagram describing a pixel circuit of a pixel array according to some embodiments of the present disclosure. Referring to FIG. 4, a pixel array 210 may include first and second pixel circuits PIX1 and PIX2, and each of the first pixel circuit PIX1 and the second pixel circuit PIX2 may include a plurality of sub-pixel circuits. Each sub-pixel circuit may be a circuit of a minimum unit, which generates photo charges based on an incident light.

For better understanding of the present disclosure, the description will be given as each of the first pixel circuit PIX1 and the second pixel circuit PIX2 includes four sub-pixel circuits, but the present invention is not limited thereto. Each of the first pixel circuit PIX1 and the second pixel circuit PIX2 may include a plurality of (e.g., eight) sub-pixel circuits, and different numbers of sub-pixel circuits may be used for the first and second pixel circuits PIX1 and PIX2.

The first pixel circuit PIX1 may include first to fourth sub-pixel circuits SPIX1 to SPIX4. The first sub-pixel circuit SPIX1 may include a first photodiode PD1 and a first transfer transistor TT1. The second sub-pixel circuit SPIX2 may include a second photodiode PD2 and a second transfer transistor TT2. The third sub-pixel circuit SPIX3 may include a third photodiode PD3 and a third transfer transistor TT3. The fourth sub-pixel circuit SPIX4 may include a fourth photodiode PD4 and a fourth transfer transistor TT4. Each of the first to fourth photodiodes PD1 to PD4 may receive a light incident from the outside and may generate photo charges based on the received light. Generated photo charges may transfer to the first FD node FD1 through the first to fourth transfer transistors TT1 to TT4 in response to first to fourth sub-transfer signals STF1 to STF4.

The first transfer transistor TT1 may connect the first photodiode PD1 to the first FD node FD1. For example, the first transfer transistor TT1 may connect or disconnect the first photodiode PD1 to or from the first FD node FD1 in response to the first sub-transfer signal STF1. The first sub-transfer signal STF1 may be included in the first transfer signal TF1.

In some embodiments, the first transfer transistor TT1 may be turned on in response to the first sub-transfer signal STF1 having the logic high level and may connect the first photodiode PD1 to the first FD node FD1. When the first transfer transistor TT1 is turned on in response to the first sub-transfer signal STF1 having the logic high level, the photo charges generated by the first photodiode PD1 may be transferred to the first FD node FD1.

Also, the first transfer transistor TT1 may be turned off in response to the first sub-transfer signal STF1 having the logic low level and may disconnect the first photodiode PD1 from the first FD node FD1. When the first transfer transistor TT1 is turned off in response to the first sub-transfer signal STF1 having the logic low level, the photo charges generated by the first photodiode PD1 may not be transferred to the first FD node FD1.

The second to fourth sub-pixel circuits SPXI2 to SPIX4 are similar to the first sub-pixel circuit SPIX1, and thus, additional description will be omitted to avoid redundancy.

A sum of photo charges which the first to fourth sub-pixel circuits SPIX1 to SPIX4 transfer to the first FD node FD1 may correspond to photo charges which the first pixel circuit PIX1 transfers to the first FD node FD1. Whether any (e.g., one or all) of the first to fourth sub-pixel circuits SPIX1 to SPIX4 transfers photo charges to the first FD node FD1 may be determined by an operating mode (e.g., the full mode or the binning mode) of the pixel array 210. How sub-pixel circuits operate depending on the operating mode of the pixel array 210 will be described in detail with reference to FIGS. 5A and 5B together.

The second pixel circuit PIX2 is similar to the first pixel circuit PIX1, and thus, additional description will be omitted to avoid redundancy.

As described above, the photo charges PC of the common node CN may correspond to the photo charges received from the first FD node FD1 and the second FD node FD2. For example, depending on a first connection signal CS1 and a second connection signal CS2, the photo charges PC of the common node CN may correspond to photo charges received from the first FD node FD1, the second FD node FD2, or both the first FD node FD1 and the second FD node FD2. Also, the photo charges stored at the first FD node FD1 may correspond to a sum of photo charges received from the first to fourth sub-pixel circuits SPIX1 to SPIX4 depending on the first to fourth sub-transfer signals STF1 to STF4.

FIG. 5A is a circuit diagram describing a pixel array operating in a full mode, according to some embodiments of the present disclosure. Referring to FIG. 5A, in the full mode, one of the first to eighth sub-pixel circuits SPIX1 to SPIX8 may be turned on, and a connection transistor corresponding to the turned-on sub-pixel circuit may be turned on.

For better understanding of the present disclosure, the description will be given as a pixel array 310 includes a pixel group (i.e., an 8-shared structure) implemented with eight sub-pixel circuits, but the present invention is not limited thereto. The pixel array 310 may include a pixel group (e.g., a 16-shared structure) implemented with a plurality of (e.g., 16) sub-pixel circuits.

Below, for better understanding of the present disclosure, the description will be given as the first sub-pixel circuit SPIX1 and the first connection transistor CT1 are turned on, but the present invention is not limited thereto. After the first sub-pixel circuits SPIX1 is read out, the second to eighth sub-pixel circuits SPIX2 to SPIX8 may be sequentially turned on, and a connection transistor (e.g., the first connection transistor CT1 or the second connection transistor CT2) corresponding to the turned-on sub-pixel circuit may be turned on.

The timing controller 150 of FIG. 2 may determine that the pixel array 310 operates in the full mode. The full mode may indicate an operating mode of the pixel array 310 which sequentially generates the pixel signals PS corresponding to photo charges generated by sub-pixel circuits. In response to determining that the pixel array 310 operates in the full mode, the timing controller 150 of FIG. 2 may generate the first transfer signal TF1 and the second transfer signal TF2 for sequentially reading out sub-pixel circuits.

In some embodiments, for example, to read out the first sub-pixel circuit SPIX1, the timing controller 150 of FIG. 2 may generate the first sub-transfer signal STF1 having the logic high level and may generate the second to eighth sub-transfer signals STF2 to STF8 having the logic low level.

In some embodiments, the first sub-pixel circuit SPIX1 may be turned on in response to the first sub-transfer signal STF1 having the logic high level and may transfer photo charges generated based on the incident light to the first FD node FD1. The second to eighth sub-pixel circuits SPIX2 to SPIX8 may be turned off in response to the second to eighth sub-transfer signals STF2 to STF8.

In some embodiments, when only the first sub-pixel circuit SPIX1 is turned on to read out the first sub-pixel circuit SPIX1, photo charges may be stored only at the first FD node FD1, and photo charges may not be stored at the second FD node FD2. Accordingly, only the first connection transistor CT1 connected between the first FD node FD1 and the common node CN should be turned on, and the second connection transistor CT2 may not be turned on.

In some embodiments, the timing controller 150 of FIG. 2 may determine whether at least one of the first to fourth sub-transfer signals STF1 to STF4 included in the first transfer signal TF1 has the logic high level. Next, the timing controller 150 of FIG. 2 may generate the first connection signal CS1 having the logic high level in response to determining that at least one of the first to fourth sub-transfer signals STF1 to STF4 included in the first transfer signal TF1 has the logic high level. In contrast, the timing controller 150 of FIG. 2 may generate the first connection signal CS1 having the logic low level in response to determining that all of the first to fourth sub-transfer signals STF1 to STF4 included in the first transfer signal TF1 have the logic low level.

For example, when a sub-pixel circuit targeted for readout from among a plurality of sub-pixel circuits is turned on, a connection transistor connecting an FD node (e.g., FD1) connected to the turned-on sub-pixel circuit and the common node CN may be turned on. Also, a connection transistor connecting an FD node (e.g., FD2) connected to the remaining sub-pixel circuits and the common node CN may be turned off. Accordingly, the photo charges PC of the common node CN may correspond to photo charges received from the turned-on sub-pixel circuit. For example, the pixel signal PS which the source follower transistor SFT generates may correspond to the photo charges generated from the turned-on sub-pixel circuit SPIX1.

As the pixel array 310 of the present invention is implemented by using a pixel group including two FD nodes FD1 and FD2, the noise of the pixel signal PS in the full mode may be reduced. For example, when a sub-pixel circuit is turned off, for example, an error that a noise occurs due to photo charge leaked out to an FD node from the sub-pixel circuit turned off may occur. The pixel array 310 of the present disclosure may reduce the noise of the pixel signal PS, which occurs when photo charges of the turned-off sub-pixel circuit are leaked out.

In detail, for example, when the first sub-transfer signal STF1 has the logic high level and the second to eighth sub-transfer signals STF2 to STF8 have the logic low level, only the first sub-pixel circuit SPIX1 may be turned on, and the second to eighth sub-pixel circuits SPIX2 to SPIX8 may be turned off. However, an error may occur, for example, when photo charges of the fifth to eighth sub-pixel circuits SPIX5 to SPIX8 turned off are leaked out to the second FD node FD2.

In a conventional pixel array, the leaked-out photo charges may be together stored at the FD node where the photo charges of the first sub-pixel circuit SPIX1 are stored, thereby causing the noise of the pixel signal PS. In the case of the pixel array 310 of the present invention, the photo charges leaked out from the fifth to eighth sub-pixel circuits SPIX5 to SPIX8 may be stored at the second FD node FD2; however, because the second connection transistor CT2 connected between the second FD node FD2 and the common node CN is turned off, the photo charges stored at the second FD node FD2 may not be transferred to the common node CN. Accordingly, the pixel array 310 of the present disclosure may reduce the noise of the pixel signal PS, which is capable of occurring when photo charges of the turned-off sub-pixel circuit are leaked out.

In addition, the structure of the pixel array 310 of the present disclosure, which reduces the noise of the pixel signal PS, may make it possible to increase the number of sub-pixel circuits constituting one pixel group. For example, when the noise of the pixel signal PS due to the photo charges leaked from one sub-pixel circuit corresponds to one bit and one pixel group includes eight sub-pixel circuits, a conventional pixel array in which one pixel group includes one FD node may generate a pixel signal whose noise corresponds to a maximum of eight bits. However, as described above, the pixel array 310 of the present disclosure, in which one pixel group includes two FD nodes, may generate a pixel signal whose noise corresponds to a maximum of four bits. For example, for the pixel array 310 to generate a pixel signal whose noise corresponds to a maximum of eight bits, the pixel array 310 of the present disclosure may include a pixel array implemented with sub-pixel circuits, the number (e.g., 16) of which is more than that of the conventional pixel array.

FIG. 5B is a circuit diagram describing a pixel array operating in a binning mode, according to some embodiments of the present disclosure. Referring to FIG. 5B, in the binning mode, all the first to eighth sub-pixel circuits SPIX1 to SPIX8 may be turned on, and the first connection transistor CT1 corresponding to the turned-on first to fourth sub-pixel circuits SPIX1 to SPIX4 and the second connection transistor CT2 corresponding to the turned-on fifth to eighth sub-pixel circuits SPIX5 to SPIX8 may be turned on.

For better understanding of the present disclosure, the description will be given as the pixel array 310 includes a pixel group (i.e., an 8-shared structure) implemented with eight sub-pixel circuits, but the present invention is not limited thereto. The pixel array 310 may include a pixel group (e.g., a 16-shared structure) implemented with a plurality of (e.g., 16) sub-pixel circuits.

The timing controller 150 of FIG. 2 may determine that the pixel array 310 operates in the binning mode. The binning mode may indicate an operating mode of the pixel array 310, in which there is generated the pixel signal PS corresponding to a sum of photo charges generated by respective sub-pixel circuits. The binning mode may be used in a low-illumination environment where the amount of light is small. In response to determining that the pixel array 310 operates in the binning mode, the timing controller 150 of FIG. 2 may generate the first transfer signal TF1 and the second transfer signal TF2 for reading out all the sub-pixel circuits.

In some embodiments, for example, to read out the first to eighth sub-pixel circuits SPIX1 to SPIX8, the timing controller 150 of FIG. 2 may generate the first to eighth sub-transfer signals STF1 to STF8 each having the logic high level. The first to eighth sub-pixel circuits SPIX1 to SPIX8 may be turned on in response to the first to eighth sub-transfer signals STF1 to STF8 each having the logic high level. In response to the first to eighth sub-transfer signals STF1 to STF8 each having the logic high level, the first to fourth sub-pixel circuits SPIX1 to SPIX4 may transfer photo charges to the first FD node FD1, and the fifth to eighth sub-pixel circuits SPIX5 to SPIX8 may transfer photo charges to the second FD node FD2.

In some embodiments, the first FD node FD1 and the second FD node FD2 where the photo charges of the first to eighth sub-pixel circuits SPIX1 to SPIX8 are stored may be connected to read out the first to eighth sub-pixel circuits SPIX1 to SPIX8. Accordingly, the timing controller 150 of FIG. 2 may generate the first connection signal CS1 and the second connection signal CS2 each having the logic high level. The first connection transistor CT1 may be turned on in response to the first connection signal CS1 having the logic high level, and the second connection transistor CT2 may be turned on in response to the second connection signal CS2 having the logic high level.

For example, the photo charges generated from sub-pixel circuits included in the first pixel circuit PIX1 may be stored at the first FD node FD1, and the photo charges generated from sub-pixel circuits included in the second pixel circuit PIX2 may be stored at the second FD node FD2. Also, the first FD node FD1 and the second FD node FD2 may be connected to the common node CN through the first connection transistor CT1 and the second connection transistor CT2. For example, the pixel signal PS which the source follower transistor SFT generates may correspond to a sum of the photo charges generated from the first to eighth sub-pixel circuits SPIX1 to SPIX8.

As described with reference to FIG. 5A, in the full mode, the pixel array 310 of the present disclosure may reduce the noise of the pixel signal PS, which is capable of occurring when photo charges of a turned-off sub-pixel circuit are leaked out, by turning off a connection transistor connecting the common node CN to an FD node which does not need to store photo charges. Accordingly, the pixel array 310 of the present disclosure may include a pixel group implemented with sub-pixel circuits, the number of which is (e.g., two times) more than that of the conventional pixel array.

As described above, because the pixel array 310 of the present disclosure is capable of including a pixel group implemented with more sub-pixel circuits than the conventional pixel array, the pixel array 310 may generate the pixel signal PS whose signal-to-noise ratio (SNR) is improved in the binning mode. For example, when the conventional pixel array includes a pixel group implemented with four sub-pixel circuits, the conventional pixel array may generate a pixel signal corresponding to a sum of photo charges generated by the respective sub-pixel circuits included in the pixel group. Meanwhile, when the pixel array 310 of the present disclosure includes a pixel group implemented with eight sub-pixel circuits, the pixel array 310 of the present disclosure may generate the pixel signal PS corresponding to a sum of photo charges generated by the respective eight sub-pixel circuits (the number of which is more than 4) included in the pixel group in the binning mode. For example, the pixel array 310 of the present disclosure may generate the pixel signal PS whose intensity is stronger than the conventional pixel array.

When the pixel signal generated by the conventional pixel array and the pixel signal PS generated by the pixel array 310 of the present disclosure include a noise of the same magnitude, because the intensity of the pixel signal PS of the pixel array 310 of the present disclosure is stronger than that of the pixel signal of the conventional pixel array, the SNR of the pixel signal PS of the pixel array 310 of the present disclosure may be greater than the SNR of the pixel signal of the conventional pixel array. Accordingly, the pixel array 310 of the present disclosure may generate the pixel signal PS whose SNR is improved in the binning mode.

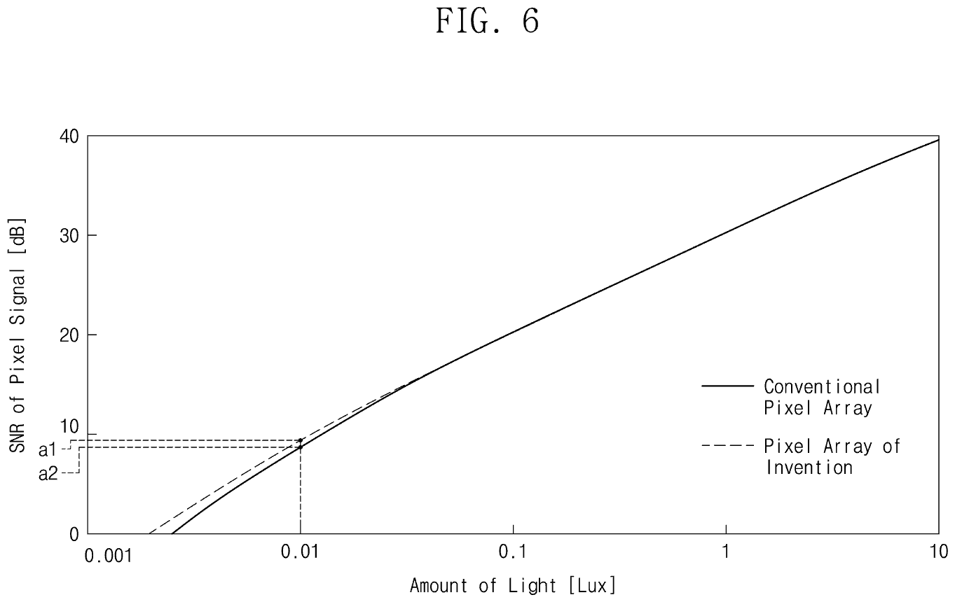

FIG. 6 is a graph describing an SNR of a pixel signal according to some embodiments of the present disclosure. Referring to FIG. 6, the SNR of a pixel signal which a pixel array of the present disclosure generated in a low-luminance environment where the amount of light is small may be greater than the SNR of a pixel signal which the conventional pixel array generates in the low-luminance environment. The conventional pixel array may include a pixel group implemented with one FD node and a plurality of sub-pixel circuits. In FIG. 6, the horizontal axis represents the amount of light incident onto each photodiode of a pixel array, and the vertical axis represents an SNR of a pixel signal.

As described with reference to FIGS. 5A and 5B, the pixel array of the present disclosure may include a pixel group implemented with sub-pixel circuits, the number of which is more than that of the conventional pixel array. Accordingly, in the binning mode, the pixel array of the present disclosure may generate the pixel signal whose intensity is stronger than the conventional pixel array.

That the amount of light 0.01 Lux may indicate that the pixel array or an image sensor including the pixel array operates in the low-luminance environment. For example, the pixel array may operate in the binning mode and may generate a pixel signal which corresponds to a sum of photo charges generated by the respective sub-pixel circuits constituting the pixel group.

When the amount of light is 0.01 Lux, the SNR of the pixel signal which the conventional pixel array generates may have a second value a2, and the SNR of the pixel signal which the pixel array of the present invention generates may have a first value a1. For example, in the binning mode, the SNR of the pixel signal which the pixel array of the present invention generates may be greater than the SNR of the conventional pixel signal. Each of the first value a1 and the second value a2 may be a real number.

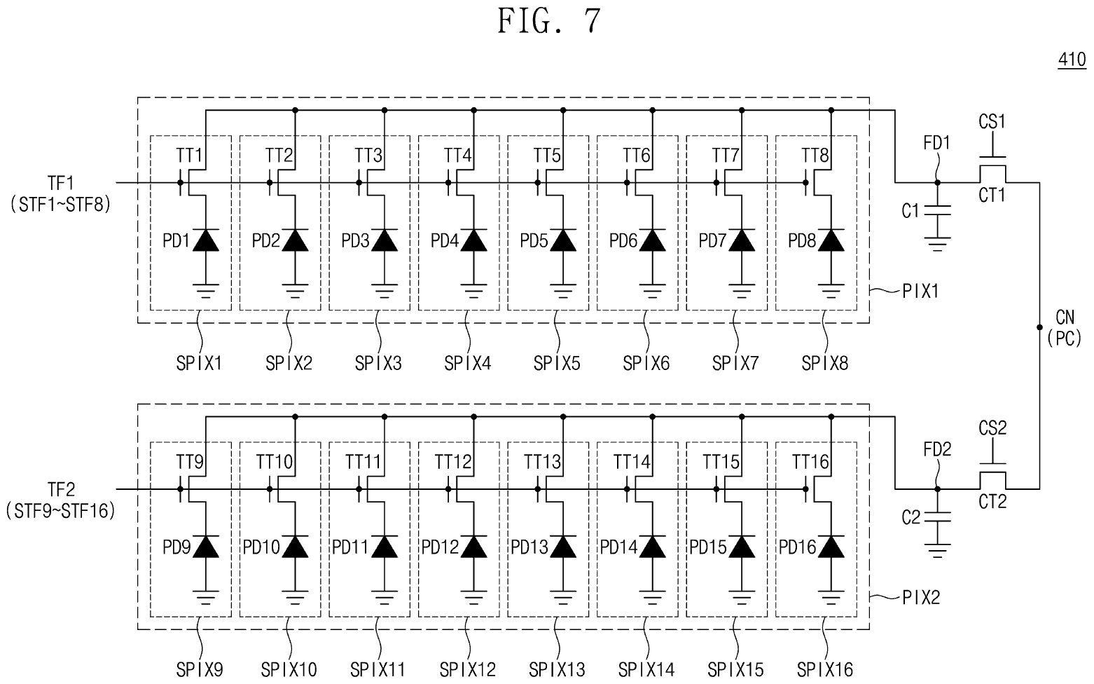

FIG. 7 is a circuit diagram describing a pixel array according to some embodiments of the present disclosure. Referring to FIG. 7, a pixel array 410 may include two pixel circuits PIX1 and PIX2 each including eight sub-pixel circuits.

For better understanding of the present disclosure, the description is given as each of the first pixel circuit PIX1 and the second pixel circuit PIX2 includes eight sub-pixel circuits, but the present invention is not limited thereto. Each of the first pixel circuit PIX1 and the second pixel circuit PIX2 may include 2 or 16 sub-pixel circuits, and different numbers of sub-pixel circuits may be used for the first and second pixel circuits PIX1 and PIX2.

The pixel array 410 is partially similar to the pixel array 210 of FIG. 4, and thus, additional description will be omitted to avoid redundancy.

The first pixel circuit PIX1 may include first to eighth sub-pixel circuits SPIX1 to SPIX8. The first to eighth sub-pixel circuits SPIX1 to SPIX8 may operate in response to first to eighth sub-transfer signals STF1 to STF8. For example, the first to eighth sub-pixel circuits SPIX1 to SPIX8 may transfer photo charges to the first FD node FD1 in response to the first to eighth sub-transfer signals STF1 to STF8.

In some embodiments, in the full mode, the first to eighth sub-pixel circuits SPIX1 to SPIX8 may transfer photo charges to the first FD node FD1 sequentially in response to the first to eighth sub-transfer signals STF1 to STF8. Also, in the binning mode, the first to eighth sub-pixel circuits SPIX1 to SPIX8 may transfer photo charges to the first FD node FD1 in response to the first to eighth sub-transfer signals STF1 to STF8.

The second pixel circuit PIX2 is similar to the first pixel circuit PIX1, and thus, additional description will be omitted to avoid redundancy.

As described with reference to FIGS. 5A and 5B, in the full mode, because an FD node connected to eight turned-off sub-pixel circuits is not connected to a common node, the pixel array 410 may generate the pixel signal PS having a noise capable of occurring due to photo charges leaked from a maximum of seven sub-pixel circuits. Meanwhile, a conventional pixel array including a pixel group implemented with one FD node and 16 sub-pixel circuits may generate the pixel signal having a noise capable of occurring due to photo charges leaked from a maximum of 15 sub-pixel circuits.

In addition, when a noise of a pixel signal capable of being error-corrected corresponds to a sum of photo charges leaked from a maximum of 7 sub-pixel circuits, the conventional pixel circuit may include a pixel group only implemented with eight sub-pixel circuits, but the pixel array 410 of the present invention may include a pixel group implemented with 16 sub-pixel circuits.

For example, because the pixel array 410 includes a pixel group implemented with more sub-pixel circuits than the conventional pixel array, the pixel array 410 may generate the pixel signal whose SNR is improved in the full mode and the binning mode. Also, compared to the conventional pixel array, in the pixel array 410, more sub-pixel circuits may share FD nodes and transistors (e.g., the first and second reset transistors RT1 and RT2, the source follower transistor SFT, and the select transistor SLT of FIG. 3), and thus, the efficiency of area of the pixel array may be improved.

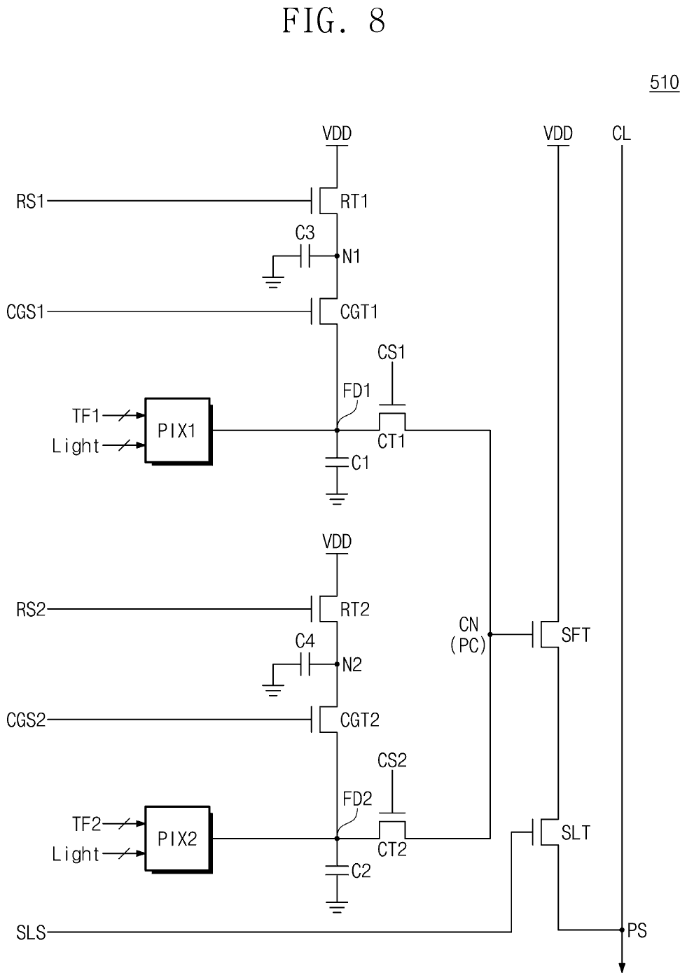

FIG. 8 is a circuit diagram describing a pixel array according to some embodiments of the present disclosure. Referring to FIG. 8, a pixel array 510 may include the first pixel circuit PIX1, the second pixel circuit PIX2, the first FD node FD1, the second FD node FD2, the first connection transistor CT1, the second connection transistor CT2, a first dual conversion gain transistor CGT1, a second dual conversion gain transistor CGT2, the first reset transistor RT1, the second reset transistor RT2, the source follower transistor SFT, and the select transistor SLT.

The pixel array 510 is partially similar to the pixel array 110 of FIG. 3, and thus, additional description will be omitted to avoid redundancy.

The first dual conversion gain transistor CGT1 may operate in response to a first dual conversion gain signal CGS1. For example, the first dual conversion gain transistor CGT1 may be turned on or turned off in response to the first dual conversion gain signal CGS1, and thus, the storage capacity of the first FD node FD1 may be adjusted. The first dual conversion gain transistor CGT1 may adjust the storage capacity of the first FD node FD1 such that a range of the intensity of light to be sensed by the first pixel circuit PIX1 is dynamically adjusted. Accordingly, a high dynamic range (HDR) may be implemented.

The first dual conversion gain transistor CGT1 may be connected between the first FD node FD1 and a first node N1. The capacity of photo charges stored at the first node N1 may correspond to a third capacitor C3. The third capacitor C3 may indicate a storage capacity of a parasitic capacitor of the first node N1.

In some embodiments, the first dual conversion gain transistor CGT1 may be turned on in response to the first dual conversion gain signal CGS1 having the logic high level. The first dual conversion gain transistor CGT1 thus turned on may be connected between the first FD node FD1 and the first node N1. In this case, the photo charges stored at the first FD node FD1 may be transferred to the first node N1. For example, when the first dual conversion gain transistor CGT1 is turned on, the storage capacity of the first FD node FD1 may increase to a sum of the first capacitor C1 and the third capacitor C3. A conversion gain corresponding to the case where the first dual conversion gain transistor CGT1 is turned on may be referred to as a “low conversion gain”.

In some embodiments, the first dual conversion gain transistor CGT1 may be turn off on in response to the first dual conversion gain signal CGS1 having the logic low level. The first dual conversion gain transistor CGT1 thus turned off may disconnect the first FD node FD1 from the first node N1. In this case, the photo charges stored at the first FD node FD1 may not be transferred to the first node N1. For example, when the first dual conversion gain transistor CGT1 is turned off, the storage capacity of the first FD node FD1 may correspond to the first capacitor C1. A conversion gain corresponding to the case where the first dual conversion gain transistor CGT1 is turned off may be referred to as a “high conversion gain”.

In the low-illumination environment where the amount of light is small, because the amount of photo charges generated from the first pixel circuit PIX1 is relatively small, the first FD node FD1 may not be easily saturated. Accordingly, the first dual conversion gain transistor CGT1 may be turned off in response to the first dual conversion gain signal CGS1 having the logic low level.

In the high-illumination environment where the amount of light is great, because the amount of photo charges generated from the first pixel circuit PIX1 is relatively great, the first FD node FD1 may be easily saturated. Accordingly, the first dual conversion gain transistor CGT1 may be turned on in response to the first dual conversion gain signal CGS1 having the logic high level. As the capacitance of the first FD node FD1 increases to a sum of the first capacitor C1 and the third capacitor C3, the first FD node FD1 may stably store the photo charges.

In some embodiments, the first dual conversion gain transistor CGT1 may include a first low dual conversion gain transistor, a first middle dual conversion gain transistor, and a first high dual conversion gain transistor. The first low dual conversion gain transistor, the first middle dual conversion gain transistor, and the first high dual conversion gain transistor may operate in response to respective control signals included in the first dual conversion gain signal CGS1.

The second dual conversion gain transistor CGT2 is similar to the first dual conversion gain transistor CGT1, and thus, additional description will be omitted to avoid redundancy.

The first and second dual conversion gain transistors CGT1 and CGT2 may make it possible for the first and second FD nodes FD1 and FD2 to stably store photo charges in various environments.

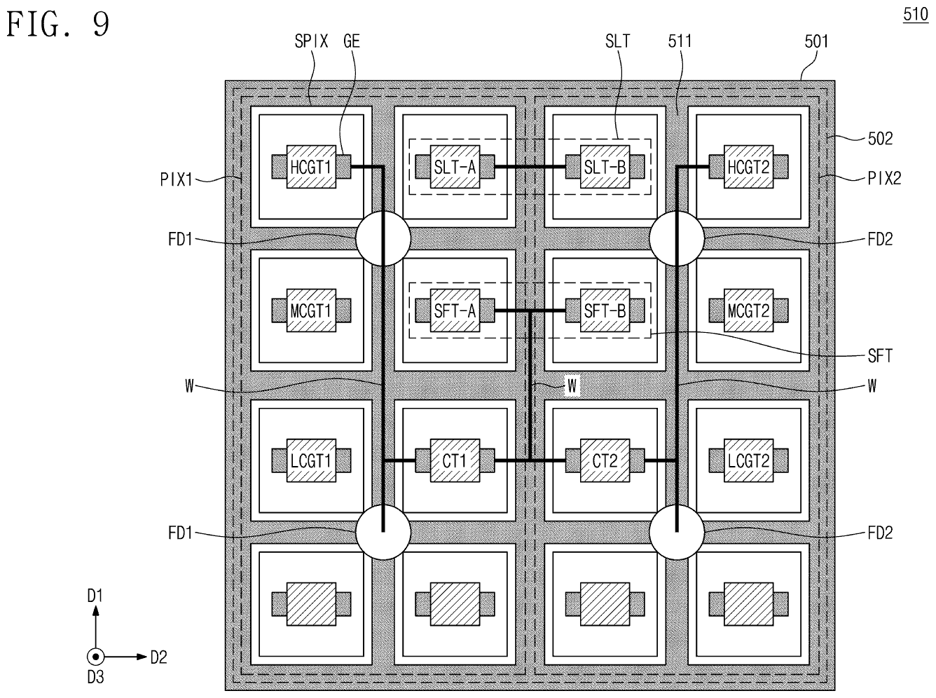

FIG. 9 is a diagram describing a layout of a pixel array according to some embodiments of the present disclosure. Referring to FIG. 9, the pixel array 510 may include the first and second pixel circuits PIX1 and PIX2, a pixel isolation layer 511, the first and second FD nodes FD1 and FD2, a wire “W”, first and second high dual conversion gain transistors HCGT1 and HCGT2, first and second middle dual conversion gain transistors MCGT1 and MCGT2, first and second low dual conversion gain transistors LCGT1 and LCGT2, the first and second connection transistors CT1 and CT2, the source follower transistor SFT, and the select transistor SLT.

The pixel array 510 may be disposed on a substrate 501. The substrate 501 may be a layer that is formed by a semiconductor substrate such as crystalline silicon, and may include a pixel region 502. For example, the pixel region 502 may include the first and second pixel circuits PIX1 and PIX2.

In an embodiment, the first low dual conversion gain transistor LCGT1, the first middle dual conversion gain transistor MCGT1, and the first high dual conversion gain transistor HCGT1 disposed in the pixel region 502 may be connected in series. In this case, the first low dual conversion gain transistor LCGT1 may be connected to the first reset transistor RT1, the first high dual conversion gain transistor HCGT1 may be connected to the first FD node FD1, and the first middle dual conversion gain transistor MCGT1 may be connected between the first low dual conversion gain transistor LCGT1 and the first high dual conversion gain transistor HCGT1.

Although not shown, in an embodiment, the first low dual conversion gain transistor LCGT1 may operate in response to a first low dual conversion gain signal LCGS1, the first middle dual conversion gain transistor MCGT1 may operate in response to a first middle dual conversion gain signal MCGS1, and the first high dual conversion gain transistor HCGT1 may operate in response to a first high dual conversion gain signal HCGS1. In an embodiment, the timing controller 150 of FIG. 2 may generate the first low dual conversion gain signal LCGS1, the first middle dual conversion gain signal MCGS1, and the first high dual conversion gain signal HCGS1.

The pixel array 510 is similar to the pixel array 510 of FIG. 8, and thus, additional description will be omitted to avoid redundancy.

The first pixel circuit PIX1 may include a plurality of sub-pixel circuits SPIX which share the first FD node FD1 and are arranged in a matrix with two rows and four columns. The sub-pixel circuits SPIX may be separated from each other by the pixel isolation layer 511.

The first pixel circuit PIX1 may be stacked on (or may overlap) any other transistors (e.g., the first high dual conversion gain HCGT1 and the select transistor SLT) in a direction facing away from a third direction D3. For example, the sub-pixel circuit SPIX of the first pixel circuit PIX1 may be stacked on (or may overlap) the first high dual conversion gain transistor HCGT1 in the direction facing away from the third direction D3, and the remaining sub-pixel circuit(s) may also be stacked on (or may overlap) the first connection transistor CT1 in the direction facing away from the third direction D3.

The second pixel circuit PIX2 is similar to the first pixel circuit PIX1, and thus, additional description will be omitted to avoid redundancy. The first FD node FD1 and the second FD node FD2 may be disposed sequentially along the second direction D2. The first pixel circuit PIX1 and the second pixel circuit PIX2 may be disposed sequentially along the second direction D2.

The pixel isolation layer 511 may prevent the cross-talk between sub-pixel circuits SPIX adjacent to each other. In a plan view, the pixel isolation layer 511 may surround each of the plurality of sub-pixel circuits SPIX. For example, the pixel isolation layer 511 may extend along a first direction D1 and a second direction D2 to surround each sub-pixel circuit SPIX. Meanwhile, the pixel isolation layer 511 may be separated by the first and second FD nodes FD1 and FD2 in the first direction D1, the second direction D2, and the third direction D3 perpendicular to the first direction D1 and the second direction D2.

The wire “W” may be stacked on (or may overlap) the sub-pixel circuits SPIX, the pixel isolation layer 511, the transistors, and the first and second FD nodes FD1 and FD2 in the third direction D3. However, the wire “W” may be insulated from the remaining components other than the components connected (or, electrically connected) thereto. Also, the wire “W” may transfer photo charges between the connected components and the first and second FD nodes FD1 and FD2.

The first high dual conversion gain transistor HCGT1 may be stacked in the third direction D3 with respect to the sub-pixel circuits SPIX. The first high dual conversion gain transistor HCGT1 may transfer photo charges to the first FD node FD1 through the wire “W” connected to the electrode GE of the first high dual conversion gain transistor HCGT1.

The first FD node FD1 may receive and store the photo charges from the first pixel circuit PIX1. The first FD node FD1 may be connected to the first connection transistor CT1 through the wire “W”.

The first connection transistor CT1 may receive photo charges from the first FD node FD1 through the electrode GE and the wire “W” and may transfer the received photo charges to the source follower transistor SFT through the wire “W”.

The second FD node FD2 and the second connection transistor CT2 are similar to the first FD node FD1 and the first connection transistor CT1, and thus, additional description will be omitted to avoid redundancy. The first FD node FD1 and the second FD node FD2 may be disposed sequentially along the second direction D2. However, for better understanding of the present disclosure, the description will be given as the first FD node FD1 and the second FD node FD2 are disposed sequentially along the second direction D2, but the present invention is not limited thereto.

In some embodiments, the select transistor SLT may be implemented with two select transistors SLT-A and SLT-B. The two select transistors SLT-A and SLT-B may be connected to each other through the wire “W” in the form of a finger, and thus, the electrical resistance of the select transistor SLT may be reduced. For example, the two select transistors SLT-A and SLT-B may be connected to in parallel between

In some embodiments, the source follower transistor SFT may be implemented with two source follower transistors SFT-A and SFT-B. The two source follower transistors SFT-A and SFT-B may be connected to each other through the wire “W” in the form of a finger, and thus, the noise of the source follower transistor SFT may be reduced.

In the above embodiments, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

According to an embodiment of the present disclosure, an image sensor and an electronic device including the same are provided.

Also, an image sensor generating a pixel signal whose signal-to-noise ratio (SNR) is improved by controlling photo charges diffused to a source follower transistor from a floating diffusion node through a connection transistor and an electronic device including the same are provided.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. An image sensor comprising:
a first pixel circuit connected to a first floating diffusion (FD) node;
a second pixel circuit connected to a second FD node;
a first reset transistor configured to reset the first FD node in response to a first reset signal;
a second reset transistor configured to reset the second FD node in response to a second reset signal;
a first connection transistor connected between the first FD node and a common node, and configured to transfer photo charges of the first FD node to the common node in response to a first connection signal;
a second connection transistor connected between the second FD node and the common node, and configured to transfer photo charges of the second FD node to the common node in response to a second connection signal; and
a source follower transistor configured to output a pixel signal corresponding to photo charges of the common node to a select transistor,
wherein the select transistor is connected between the source follower transistor and a column line, and is configured to transfer the pixel signal to the column line in response to a selection signal.

2. The image sensor of claim 1, wherein the first pixel circuit includes a plurality of sub-pixel circuits, and
wherein each of the plurality of sub-pixel circuits includes:
a photodiode configured to generate photo charges based on an incident light; and
a transfer transistor configured to connect the photodiode and the first FD node.

3. The image sensor of claim 2, wherein the first pixel circuit includes first to fourth sub-pixel circuits, and
wherein the transfer transistors of the first to fourth sub-pixel circuits are configured to transfer photo charges of the first to fourth sub-pixel circuits to the first FD node in response to first to fourth sub-transfer signals, respectively.

4. The image sensor of claim 1, wherein the first FD node is configured to store photo charges received from the first pixel circuit,
wherein the second FD node is configured to store photo charges received from the second pixel circuit, and
wherein the photo charges of the common node include the photo charges received from the first FD node or the second FD node.

5. The image sensor of claim 1, further comprising:
a first dual conversion gain transistor connected between the first FD node and a first node connected to the first reset transistor, and configured to transfer photo charges of the first FD node to the first node in response to a first dual conversion gain signal; and
a second dual conversion gain transistor connected between the second FD node and a second node connected to the second reset transistor, and configured to transfer photo charges of the second FD node to the second node in response to a second dual conversion gain signal.

6. The image sensor of claim 5, wherein the first node is configured to store photo charges received from the first pixel circuit, and
wherein the second node is configured to store photo charges received from the second pixel circuit.

7. The image sensor of claim 1, wherein the source follower transistor is configured to:
when the first connection transistor is turned on and the second connection transistor is turned off, generate the pixel signal corresponding to photo charges stored at the first FD node,
when the first connection transistor is turned off and the second connection transistor is turned on, generate the pixel signal corresponding to photo charges stored at the second FD node, and
when the first connection transistor is turned on and the second connection transistor is turned on, generate the pixel signal corresponding to photo charges stored at both of the first FD node and the second FD node.

8. An image sensor comprising:
a pixel array; and
a timing controller configured to control the pixel array,
wherein the pixel array includes:
a first pixel circuit connected to a first floating diffusion (FD) node;
a second pixel circuit connected to a second FD node;
a first reset transistor configured to reset the first FD node in response to a first reset signal;
a second reset transistor configured to reset the second FD node in response to a second reset signal;
a first connection transistor connected between the first FD node and a common node, and configured to transfer photo charges of the first FD node to the common node in response to a first connection signal;
a second connection transistor connected between the second FD node and the common node, and configured to transfer photo charges of the second FD node to the common node in response to a second connection signal; and
a source follower transistor configured to output a pixel signal corresponding to photo charges of the common node to a select transistor,
wherein the select transistor is connected between the source follower transistor and a column line, and is configured to transfer the pixel signal to the column line in response to a selection signal.

9. The image sensor of claim 8, wherein the timing controller is configured to:
generate a first transfer signal including a plurality of sub-transfer signals to be provided to the first pixel circuit,
determine whether at least one of the plurality of sub-transfer signals has a logic high level;
generate the first connection signal having the logic high level in response to determining that at least one sub-transfer signal has the logic high level, and
generate the first connection signal having a logic low level in response to determining that all of the plurality of sub-transfer signals have the logic low level.

10. The image sensor of claim 9, wherein the timing controller is configured to:
determine one of a full mode and a binning mode as an operating mode of the image sensor based on an amount of light incident onto the pixel array, and
generate the first transfer signal based on the operating mode.

11. The image sensor of claim 8, wherein the pixel array further includes:
a first dual conversion gain transistor connected between the first FD node and a first node connected to the first reset transistor, and configured to transfer photo charges of the first FD node to the first node in response to a first dual conversion gain signal; and
a second dual conversion gain transistor connected between the second FD node and a second node connected to the second reset transistor, and configured to transfer photo charges of the second FD node to the second node in response to a second dual conversion gain signal.

12. The image sensor of claim 11, wherein the timing controller is configured to generate the first dual conversion gain signal having a logic low level in response to the first connection signal having the logic low level.

13. The image sensor of claim 8, wherein the first pixel circuit includes a plurality of sub-pixel circuits, and
wherein each of the plurality of sub-pixel circuits includes:
a photodiode configured to generate photo charges based on an incident light; and
a transfer transistor configured to connect the photodiode and the first FD node.

14. The image sensor of claim 13, wherein the first pixel circuit includes first to fourth sub-pixel circuits, and
wherein the transfer transistors of the first to fourth sub-pixel circuits are configured to transfer photo charges of the first to fourth sub-pixel circuits to the first FD node in response to first to fourth sub-transfer signals, respectively.

15. The image sensor of claim 8, wherein the source follower transistor is configured to:
when the first connection transistor is turned on and the second connection transistor is turned off, generate the pixel signal corresponding to photo charges stored at the first FD node,
when the first connection transistor is turned off and the second connection transistor is turned on, generate the pixel signal corresponding to photo charges stored at the second FD node, and
when the first connection transistor is turned on and the second connection transistor is turned on, generate the pixel signal corresponding to photo charges stored at both of the first FD node and the second FD node.

16. An image sensor comprising:
a substrate including a pixel region;
a first pixel circuit and a second pixel circuit disposed in the pixel region of the substrate so as to be adjacent in a first direction, each of the first pixel circuit and the second pixel circuit including a plurality of sub-pixel circuits;
a pixel isolation layer configured to:
penetrate the substrate and to surround the pixel region, and
isolate the plurality of sub-pixel circuits in the first direction and a second direction perpendicular to the first direction;
a first floating diffusion (FD) node region disposed in the pixel region and disposed adjacent to the plurality of sub-pixel circuits of the first pixel circuit;
a second FD node region disposed in the pixel region and disposed adjacent to the plurality of sub-pixel circuits of the second pixel circuit;
a first transistor region disposed on the pixel region of the substrate, and configured to overlap the first pixel circuit in a third direction perpendicular to the first direction and the second direction; and
a second transistor region disposed on the pixel region of the substrate, and configured to overlap the second pixel circuit in the third direction,
wherein each of the plurality of sub-pixel circuits includes:
a photodiode configured to generate photo charges based on an incident light; and
a transfer transistor stacked on the photodiode in the third direction, and configured to connect the photodiode to a corresponding FD node region of the first and second FD node regions,
wherein the first FD node region and the second FD node region are sequentially disposed in the first direction,
wherein the first transistor region includes:
a first high dual conversion gain transistor including a first end and a second end connected to the first FD node region;
a first connection transistor including a first end and a second end connected to the first FD node region;
a first source follower transistor including a first end and a gate terminal connected to the first end of the first connection transistor; and
a first select transistor including a first end and a second end connected to the first end of the first source follower transistor,
wherein the second transistor region includes:
a second high dual conversion gain transistor including a first end and a second end connected to the second FD node region;
a second connection transistor including a first end and a second end connected to the second FD node region;
a second source follower transistor including a first end and a gate terminal connected to the first end of the second connection transistor; and
a second select transistor including a first end and a second end connected to the first end of the second source follower transistor,
wherein each of the first and second source follower transistors is configured to transfer a pixel signal corresponding to photo charges of at least one of the first FD node region and the second FD node region, and includes the gate terminal electrically connected to:
one of the first and second FD node regions through a corresponding one of the first and second connection transistors, or
both of the first and second FD node regions through the first and second connection transistors, and
wherein each of the first and second select transistors is configured to output the transferred pixel signal from the first end of each of the first and second select transistors.

17. The image sensor of claim 16, further comprising:
a wire stacked on the first transistor region in the third direction, and configured to connect the first high dual conversion gain transistor, the first FD node region, and the first connection transistor to each other.

18. The image sensor of claim 16, wherein the first transistor region further includes:
a first low dual conversion gain transistor and a first middle dual conversion gain transistor connected in series, and the first middle dual conversion gain transistor connected between the first low dual conversion gain transistor and the first high dual conversion gain transistor, and
wherein the second transistor region further includes:
a second low dual conversion gain transistor and a second middle dual conversion gain transistor connected in series, and the second middle dual conversion gain transistor connected between the second low dual conversion gain transistor and the second high dual conversion gain transistor.

19. The image sensor of claim 16, further comprising:
a wire stacked on the first transistor region and the second transistor region in the third direction, and configured to connect the first source follower transistor to the second source follower transistor.

20. The image sensor of claim 16, further comprising:
a wire stacked on the first transistor region and the second transistor region in the third direction, and configured to connect the first select transistor to the second select transistor.
